(19) United States
(12) Patent Application Publication
(10) Pub. No.: US 2005/0034664 A1
(43) Pub. Date: Feb. 17, 2005

(54) Apparatus for depositing

(76) Inventors: Won Yong Koh, Daejeon-city (KR); Won Gu Kang, Daejeon-city (KR)

Correspondence Address: MARGER JOHNSON & MCCOLLOM PC, 1030 SW MORRISON STREET, PORTLAND, OR, 97205, US

(21) Appl. No.: 10/495,156

(22) PCT Filed: Nov. 8, 2002
(86) PCT No.: PCT/KR02/02078

(30) Foreign Application Priority Data
Nov. 8, 2001 (KR) 2001-69598

(51) Int. Cl. C23C 16/00

(52) U.S. Cl. 118/719; 118/715

(57) ABSTRACT

An apparatus constructed with a plural of independent reactors for depositing thin films is provided. The apparatus includes a chamber consisting of a base plate, a chamber wall and a chamber cover. A plural of identical and independent reactors are mounted inside the chamber, and each reactor has two parts; a reactor lower body and a reactor upper body, where the reactor upper body is fixed to the chamber cover and the reactor lower body is fixed to the base plate and moves up and down, thereby the up position of the reactor lower body makes a contact with the reactor upper body and thus providing a vacuum-tight processing space. Since a plural of identical and independent reactors are used, the processing steps and conditions developed for a single substrate type of reactor can be used for multiple reactors with minor adjustments, by utilizing a relatively symmetrical process gas supply inlet tube and process gas inlet tube and process gas exhaust tube arrangements. Such an arrangement also leads to high throughput, low cost and compact designs with tight footprints.

### CROSS-REFERENCE TO RELATED APPLICATION DATA

This application claims priority from Korean Application No. 2001-69598 filed Nov. 8, 2001; and PCT International Application No. PCT/KRO2/02078 filed Nov. 8, 2002.

### BACKGROUND OF THE INVENTION

1. Field of the Invention

The present invention relates to an apparatus for depositing, specifically, to an apparatus equipped with several independent reactors, thereby the apparatus is capable of processing a plural of semiconductor substrates per unit time for a throughput improvement.

2. Description of the Related Art

Due to highly paced development of very high level of circuit integration in semiconductors, the process of forming thin films plays a very significant role in semiconductor manufacturing processes. One of the most widely used method is a chemical vapor deposition (CVD) method, wherein a thin film is formed on the surface of a substrate in a reactor by feeding a source material in gaseous state into a reactor.

In utilizing a chemical vapor deposition method, there are two major types of apparatus; the first type is a batch type, where thin films are formed on a plural of substrates simultaneously, in a reactor, and the second type is a single wafer type, where a thin film is formed on each substrate one at a time in sequence using a single reactor. In a conventional batch type of chemical vapor deposition apparatus, where a plural of substrates are loaded in a reactor and thin films on each substrate are formed simultaneously, the flow and quantity of the source gas may vary depending upon the location of each substrate in the reactor and the design of the reaction chamber.

Therefore, use of a single wafer type is advantageous when a thin film with uniform thickness is to be formed on a large substrate, because the uniformity of the flow and the quantity of the source gas can be readily controlled in a single wafer type of reactor environment. However, there is a limit in using single wafer type of CVD apparatus due to its throughput.

### SUMMARY OF THE INVENTION

According to the present invention, a method for forming thin films on a plural of substrates simultaneously as well as controlling the uniformity of the flow and the quantity of the source gas feeding into substrate in a reactor, is disclosed.

In order to achieve the objects of solving the afore-described problems, according to the present invention, a reaction chamber is defined as a chamber surrounded by a base plate, a chamber wall and a chamber cover, where said base plate, chamber wall, and chamber cover defines the inner part of said reaction chamber, according to the present invention, a thin film deposition apparatus comprises at least two reactors, where said reactor consists of three major parts; a reactor upper body that is fixed to the inside ceiling of said chamber cover, a reactor lower body that defines the interior of said reactor together with said reactor upper body and moves up and down, a substrate supporting pin that is installed in the reactor lower body and supports a loaded substrate when the reactor lower body moves downward. On the side of said chamber wall, an opening through which a substrate is loaded and unloaded is located. The present invention discloses such a thin film deposition apparatus afore-described. Said reactor lower body is fixed to said base plate, and said base plate may be equipped with a drive for rotating said reactor lower body.

Another aspect of the present invention, said thin film formation apparatus disclosed previously may be equipped with a set of hook-shaped arms that rotates so that a substrate can be easily loaded or unloaded in and out of said reactor.

According to yet another aspect of the present invention, said thin film formation apparatus disclosed here may be additionally equipped with a set of hook-shaped arms that not only rotates but also moves up and down so that a substrate can be even more easily loaded and unloaded in and out of said reactor.

According to yet another aspect of the present invention, the afore-described thin film formation apparatus disclosed here may be additionally equipped with two rod-shaped arms for the purpose of loading and unloading a substrate in and out of said reactor.

Another aspect of the present invention, optionally, the base plate may be rotated for loading and unloading the substrate, in which case, only one arm is needed instead of one arm for each reactor.

### BRIEF DESCRIPTION OF THE DRAWINGS

The above and other features and advantages of the present invention will become more apparent by describing in detail exemplary embodiments thereof with reference to the attached drawings in which:

FIG. 1A is a schematic drawing illustrating a thin film deposition apparatus in Embodiment 1 according to the present invention;

FIG. 1B is a cross-sectional drawing of the thin film deposition apparatus in FIG. 1A;

FIG. 2A is a schematic drawing of the top view of a thin film deposition apparatus disclosed in Embodiment 2 according to the present invention;

FIG. 2B is a cross-sectional drawing of the thin film deposition apparatus in FIG. 2A along the dotted line A-A′;

FIG. 2C is a cross-sectional drawing of a thin film deposition apparatus disclosed in Embodiment 3 according to the present invention, along the dotted line A-A′ similarly to FIG. 2A; and

FIGS. 3A and 3B are two schematic drawings of the top views of a thin film deposition apparatus in Embodiment 4 according to the present invention, showing two different positions of the arms.

### DETAILED DESCRIPTION OF THE INVENTION

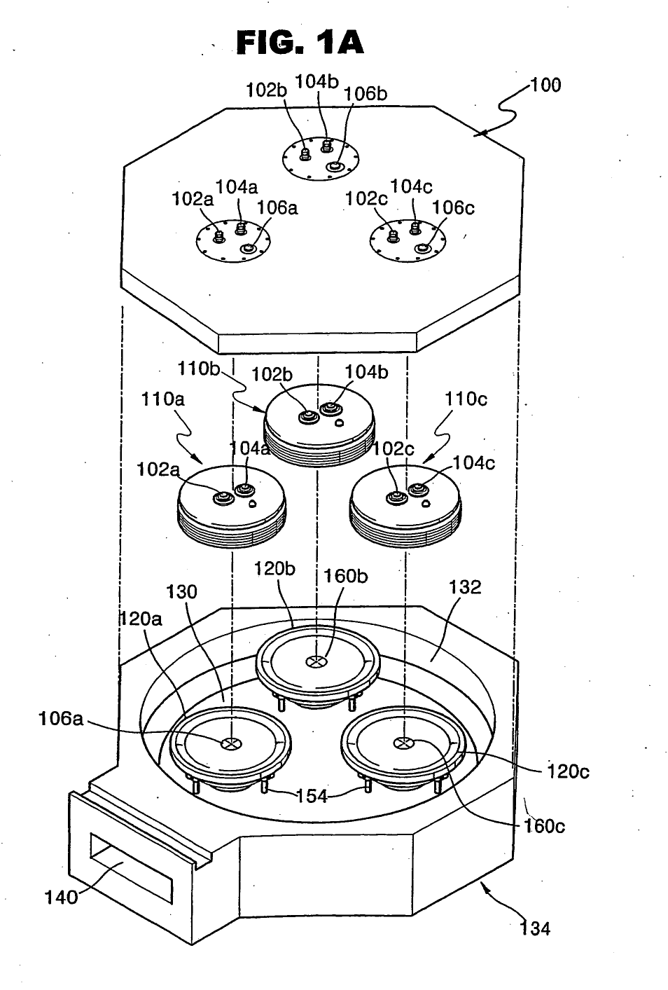

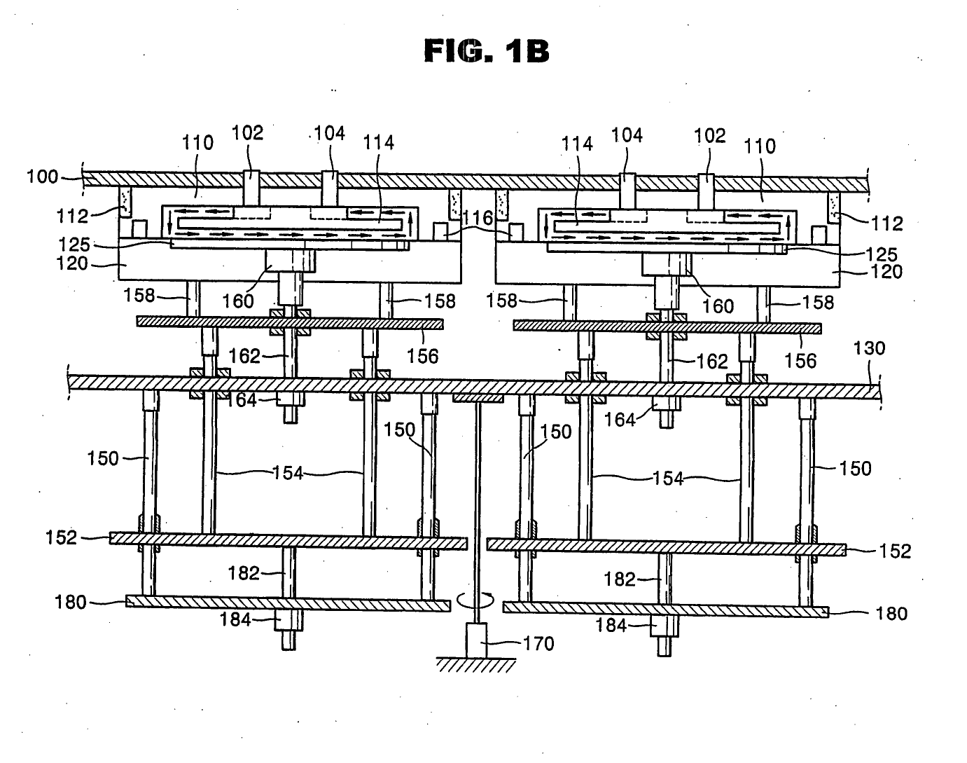

Four embodiments for carrying out the present invention are described in detail in the following in reference to FIGS. 1A through 3B. However, the best modes for carrying out the present invention are described below in order to explain the underlying basic principles and ideas of the present invention, and those who are familiar with the art should be able to derive variations of and modify the best modes presented here. The best modes presented here are not intended to limit the basic principles and ideas of the present invention. Same item numbers or alphabets used in the figures mean that they are same kinds of parts, but not necessarily physically the same parts.

Embodiment 1

FIG. 1A is a schematic drawing of an apparatus for forming thin films having three independent reactors according to the first embodiment of the present invention.

Referring to FIG. 1A, the chamber 100 and 135 is equipped with three independent single substrate type of reactors for depositing a thin film on the surface of each substrate in each reactor. In the following description only one reactor is considered unless specified otherwise because the reactors are identical. Each reactor has a reactor upper body 110a, 110b, 110c, a reactor lower body 120a, 120b, 120c, and a supporting pin 160a, 160b, 160c which is mounted in the reactor lower body 120a, 120b, 120c, and the inferior of a reactor is defined by a reactor upper body 110, 110b, 110c and a reactor lower body 120a, 120b, 120c. The reactor upper body 110a, 110b, 110c is fixed to the chamber cover 100, wherein the reactor is equipped with a gas inlet 102a, 102b, 102c and a gas outlet 104, 104b, 104c which are the passageways for the source gases. In FIG. 1A, a reactor upper body 110a, 110, 110c is equipped with a source gas inlet 102, 102b, 102c and a source gas outlet 104a, 104b, 104c, and these source gas inlet 102a, 102b, 102c and source gas outlet 104a, 104b, 104c are connected to a separate source gas supply apparatus as well as a gas exhaust apparatus, respectively, through the chamber cover 100 shown in FIG. 1A. However, there may be only one gas distribution apparatus connected to the chamber cover 100. In the source gas supply apparatus, the source gas supply tubes (not shown) may be optionally connected individually to the source gas inlet holes 102a, 102b, 102c on each reactor upper body 110a, 110b, 110c in such a way that said source gas supply tubes (not shown) are arranged mutually symmetrically with respect to the relative locations of the source gas inlet holes 102a, 102b, 102c on the reactors. Likewise, the gas outlet tubes (not shown) connected to each gas outlet hole 104a, 104b, 104c may be arranged mutually symmetrically, and then connected to one gas exhaust tube (not shown) and then to a vacuum pump (not shown). Under the substrate susceptor(not shown) in a reactor lower body 120a, 120b, 120c, a heater (not shown) is installed for heating said substrate as necessary. The reactor lower body 120a, 120b, 120c moves up and down. The reactor lower body 120a, 120b, 120c is lowered for loading and unloading a substrate. When a substrate is loaded after moving the reactor lower body 120, 120b, 120c to a low position, the reactor lower body 120a, 120b, 120c is moved up so that the reactor lower body 120a, 120b, 120c is locked into the reactor upper body 110a, 110b, 110c, and vacuum-tight sealed, thereby, the reactor lower body 120a, 120b, 120c and the reactor upper body 110a, 110b, 110c in pairs form a vacuum-tight sealed reactor suitable for either a chemical vapor deposition or an atomic layer deposition processes. Here, the substrate supporting pin 160a, 160b, 160c supports the substrate inside the reactor when the reactor lower body 120a, 120b, 120c is lowered for unloading said substrate, where the supporting pin stays stationary through a hole at the bottom of the reactor lower body 120a, 120b, 120c ever if the reactor lower body 120a, 120b, 120c is moved to down position.

Said three reactor lower bodies 120a, 120b, 120c are attached to the base plate 130, where the base plate 130 rotates so that the substrates can be easily loaded and unloaded. The base plate 130 on which three reactor lower bodies 120a, 120b, 120c are attached so that the base plate 130 can be rotated. On a side of the chamber wall 132, a substrate loading and unloading gate 140 through which wafers can be carried in and out is provided. Through this substrate loading and unloading gate 140, the substrates can be loaded and unloaded to and from each reactor.

More specifically describing, in detail, the mechanisms of loading and unloading the substrates into and out of the three reactors, the reactor lower body 120a, 120b, 120c is moved down ward in order to separate it from the reactor upper body 110a, 110b, 110c, wherein the supporting pins 160a, 160b, 160c remain fixed to the base plate 130, thereby these pins protrude above the base plate 130.

Next, the base plate 130 is rotated so that the first substrate supporting pin 160a is lined up with the substrate loading and unloading gate 140 for loading and unloading a substrate (not shown). To load a substrate into a reactor, the substrate transport mechanism (not shown) moves a substrate through the substrate loading and unloading gate 140 and place the substrate on the substrate supporting pin 160a, and then the base plate 130, to which the reactor lower bodies 120a, 120b, 120c are attached, is rotated 120° so that the second substrate supporting pin 160b is lined up with the substrate loading and unloading gate 140. Likewise, the substrate transport mechanism (not shown) places another substrate on the second substrate supporting pin 160b, and the base plate 130 is rotated by another 120° so that the third substrate supporting pin 160c is lined up with the substrate loading and unloading gate 140. To continue the operation, a third substrate is placed on the third substrate supporting pin 160c through the substrate load/unload gate 140. Next, the reactor lower bodies 120a, 120b, 120c are raised to contact with the reactor upper bodies 110a, 110b, 110c to make a vacuum-tight compressed closure between the reactor upper and lower bodies 120a to 102a, 120b to 102b, 120c to 104c, thereby these three reactors provide three independent reactors ready for a chemical vapor deposition or an atomic layer deposition operations. The substrates can be unloaded by following the afore-described steps in the reversed order.

FIG. 1B is a cross-sectional drawing illustrating another aspects of the best mode described in Embodiment 1 above according to the present invention. Referring to FIG. 1B, the chamber cover 100 is equipped with a plural of gas inlet holes 102 and a plural of gas outlet holes 104. Here, even though a chamber can accommodate one or more reactors, for the purpose of illustration using FIG. 1B it is assumed that two reactors, even though not limited to, are attached to a chamber. However, for the description of the embodiment to follow, only one reactor is used for simplified illustration purposes of the principles and ideas of the present invention. In addition, a reactor upper body 110 is attached to the chamber cover 100 by using a fastening mechanism (not shown in FIG. 1B, but 106a, for example, in FIG. 1A). In the reactor upper body 110, a gas inlet hole 102 and a gas outlet hole 104 are installed in such a way that they pass through the chamber cover and then go to the outside to provide gas passage-ways for the reactor, referring to FIG. 1B.

Also, shown in FIG. 1B is a gas flow control plate 114 suitable for atomic layer deposition applications, wherein a shower head type (not shown) of gas distribution unit is sometimes better suited for chemical vapor deposition applications.

Examples of reactor consists of a reactor lower body and a reactor upper body with a gas inlet hole and a gas outlet hole installed on it are disclosed in Korean Patent Applications KR1999-0023078, KR2000-0044823 and KR2001-0046802.

The substrate 125 on which a thin film is to be deposited is loaded into the reactor lower body 120, wherein a heater (not shown) is installed underneath the reactor lower body 120 to heat the substrate 125. The reactor lower body 120 is attached to the base plate 130 that can be rotated, for which a master drive motor 170 is mounted for rotating the base plate 130. On the other hand, the reactor lower body 120 is movable up and down, so that a substrate can be loaded at its “low” position. Followed by “up” position in such a way that the reactor lower body 120 and the reactor upper body 110 are pressed together to make a good vacuum-tight contact between them, and their interior becomes a reaction chamber.

Again, referring to FIG. 1B, the reactor lower body 120 is fixed to a connecting platform 156 through the fixing pins 158 and also the connecting platform 156 is fixed to a movable plate 152, which moves up and down by a main drive 184 fixed to a fixed plate 180 through a drive shaft 182. In turn, the fixed plate 180 is connected to the base plate 130 through fixing shaft 150.

Therefore, following the reversed order, the main drive 184 moves the movable plate 152 up and down, and in turn the movable plate 152 moves the connecting platform up and down through two connecting rods 154, and finally a link platform 156 moves the reactor lower body 120 up and down.

On the other hand, optionally, in order to load and unload a substrate 125 easily from and to the reactor lower body 120 a substrate supporting pin drive unit may be installed. The substrate supporting pin drive unit consists of a substrate supporting pin 160, a center shaft 162 of which the top part is connected to the substrate supporting pin 160, and a center drive motor 164 that drives the center shaft 162. Here, the substrate supporting pin 160 is installed in the reactor lower body 120 through a hole at the center as shown in FIG. 1B.

The operations of the reactor lower body drive unit and the substrate supporting pin drive unit allows the reactor lower body 120 to move upward so that the reactor lower body 120 makes a vacuum-tight contact with the reactor upper body 110 for forming a thin film on the surface of a substrate. Upon completion of the thin film formation, the reactor lower body 120 is moved downward, but the processed substrate 125 is separated from the reactor lower body 120 since the processed substrate 125 is supported by the substrate supporting pin 160. Once the substrate supporting pin is separated completely from the reactor lower body 120, the height of the substrate supporting pin 160 can be adjusted by using the center drive motor 164, optionally and if necessary, so that the height of the substrate can be lined up with the substrate transport unit (not shown) for safe unloading of the processed substrate.

Embodiment 2

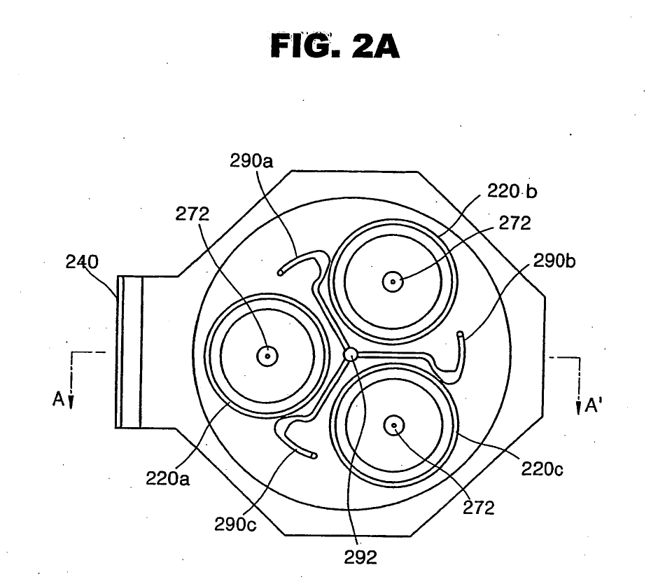

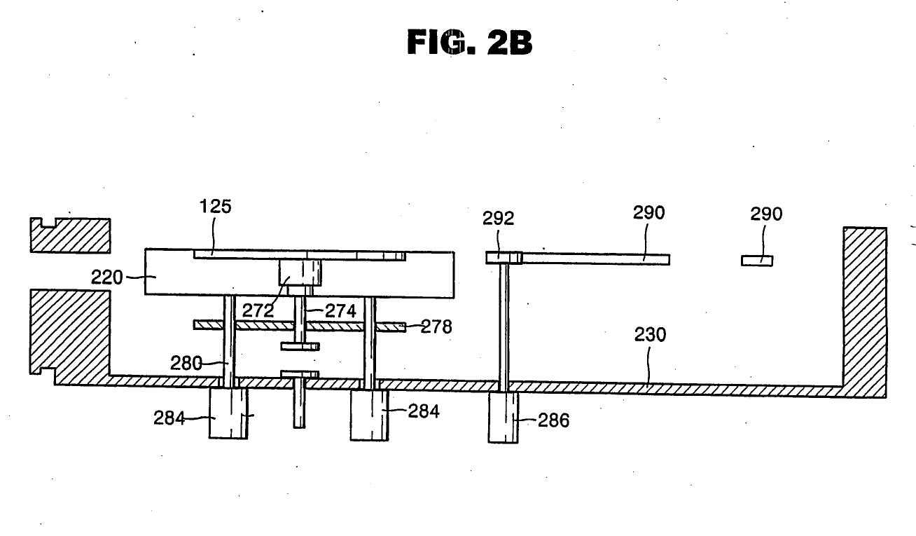

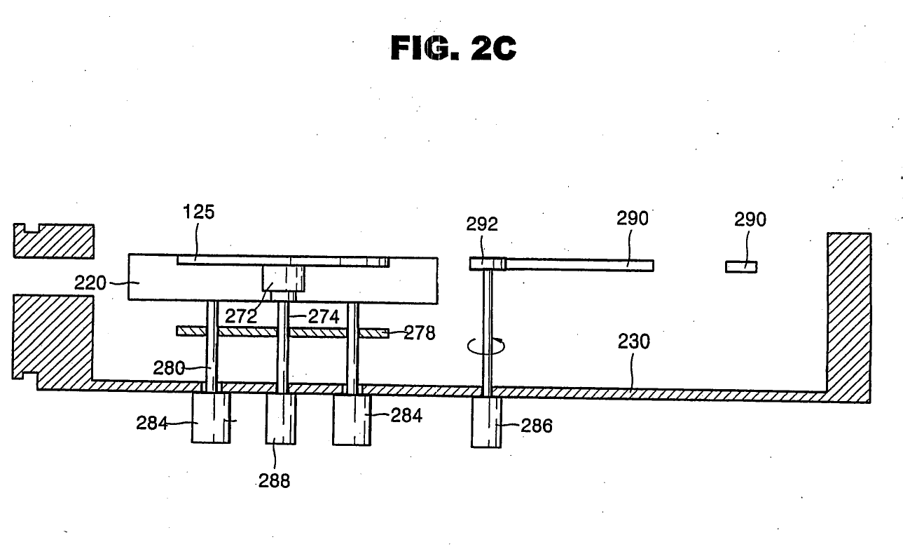

FIG. 2A is a schematic drawing of a top view of a thin film formation apparatus according to the present invention as a second embodiment. FIG. 2B is a cross-sectional drawing of FIG. 2A along the dotted line A-A′. Here, FIG. 2A is an illustration of the top view of a reactor without the chamber cover 100 as well as the reactor upper bodies 110. Therefore, the description of the chamber cover 100 (not shown) and the reactor upper bodies 110 (not shown) are omitted here, since they are identical to those in Embodiment 1.

Referring to FIG. 2A, underneath the substrate susceptor (not shown) in the reactor lower body 220a, 220b, 220c (only singular is used for the descriptions to follow), a heater (not shown) for heating the substrate is installed. The reactor lower body 220a, 220b, 220c moves up and down, therefore a substrate is loaded or unloaded when the reactor lower body is in “low” position. Once a substrate to be processed is safely loaded onto the susceptor of the reactor lower body 220a, 220b, 220c, the reactor lower body is moved upward so that the reactor lower body makes a vacuum-tight contact with the reactor upper body to set up for a reactor readying for a chemical vapor deposition or an atomic layer deposition. The reactor lower body 220a, 220b, 220cmoveds up and down by an air pressure cylinder or a liquid pressure cylinder. Also, each one of the reactor lower bodies 220a, 220b, 220c is equipped with at least one substrate supporting in pin 272 with is installed at the center of the reactor lower body 220a, 220b, 220c.

According to the present invention, the chamber body is equipped with three arms 290a, 290b, 290c for loading and unloading a substrate. Each arm 290a, 290b, 290c is attached to a arm axis 292, and this arm axis moves up and down as well as rotates by a set of drives 286 shown in FIG. 2B. The arms 290a, 290b, 290c have a shape of a hook. The inner open area of said hook-shaped arm is larger than the diameter of a substrate supporting pin 272. Three arms 290a, 290b, 290c receive three substrates (not shown) transported into the chamber through the substrate loading and undoding gate 240, and places those three substrates on the substrate susceptor (not shown) at the bottom of the reactor lower body 220a, 220b, 220c. After safely placing three substrates inside of each reactor lower body, the arms 290a, 290b, 290c return to a “park” position so that they do not interfere with the rest of the operation of the reactor. The “park” position of the arms 290a, 290b, 290c is shown in FIG. 2A.

Referring to FIG. 2B, a drive unit that drives the reactor lower body 220a, 220b, 220c consists of an air pressure cylinder 284 that is fixed to the bottom of the base plate 230, a drive axis 280 that connects the air pressure cylinder and the reactor lower body. 220a, 220b, 220c, and a movable plate 278 that adjusts a balance between the drive axes 280 when more than one drive axes are installed. In order to load and unload a substrate (not shown) into and out of a reactor, an air pressure cylinder 284 moves the reactor lower body 220a, 220b, 220c downward so that the reactor lower body 220a, 220b, 220c is separated from the reactor upper body (not shown), thereby said reactor opens. The substrate supporting pin 272 located at the center of the reactor lower body 220a, 220b, 220c is connected to the center axis 274, therefore the substrate supporting pin 272 stops moving ward at a predetermined height. Here, the substrate supporting pin 272 does not have to move downward after all, by design, optionally. The reactor lower body 220a, 220b, 220c continues moving downward, but the substrate 225 stops moving downward since the substrate is supported by the substrate supporting pin 272, thereby, the substrate (not shown) is separated from the reactor lower body 220a, 220b, 220c. The height at which the substrate stops moving is determined by the position of the substrate transport apparatus in such a way the transport of the substrate for loading and unloading the substrate by the substrate transport arm 290a, 290b, 290c, where the heigh of the arms can be adjusted by changing the lengths of the center axis 274 and the substrate supporting pin 272.

Again, referring to FIG. 2A, the method of loading a substrate (not shown) onto the reactor lower body 220a, 220b, 220c is described in detail in the following. When the given three reactors are emty to start with three reactor lower bodies 220a, 220b, 220c are lowered, and raise the height of the arms 290a, 290b, 290c are raised above the hight of the three substrate supporting pins 272 (three identical item numbers).

The arm 290a, 290b, 290c is rotated by 60° around the arm axis 292 counter clockwise (or clockwise) from the “park” position of the arms as shown in FIG. 2A, so that the first arm 290a moves in line with the first reactor lower body 220a, thereafter the first substrate 125 is moved from the outside of the reactor into the reactor lower body 220a area through the substrate loading and unloading gate 240, and then the first substrate is placed on the first arm 290a by lowering the first substrate supporting pin 272. Next, the arms are rotated by 120° counter clockwise (or clockwise) around the arm axis 292 in such a way that the second arm 290b is lined up with the first reactor lower body 220a, and then a second substrate (not shown) is transported into the first reactor lower body 220a area through the substrate loading and unloading gate 240 and the second substrate (not shown) is placed on the second arm 290b by lowering the first substrate supporting pin 272.

Likewise, the arms are rotated by another 120° counter clockwise (or clockwise) and a third substrate is placed on the third arm 290c by lowering the first substrate supporting pin. Therefore, the first substrate, the second substrate and the third substrate are lined up with the second, the third and the first reactor lower bodies, 220b, 220c, 220a. At this time all three substrate supporting pins 270 are in “lower” position than the arms 290a, 290b, 290c. Next, all three arms 290a, 290b, 290c are lowered (lower than said three substrate supporting pins 272) by lowering the arm axis 292, so that all three substrate supporting pins 272 support and hold the three substrates (not shown), respectively. At this position, the substrate support pins 272 and the three arms 290a, 290pb, 290c do not interfere with each other. Next, the arm axis 292 is rotated by 60° either clockwise or counter clockwise so that the arms do not interfere with the reactor lower bodies 220a, 220b, 220c. At this point, all three substrates are in place on the susceptors in each one of the three reactor lower bodies 220a, 220b, 220c. Next, the three reactor lower bodies 220a, 220b, 220c are raised until they lock into the reactor upper bodies (not shown), respectively, so that they form three vacuum-tight reactors ready for either chemical vapor deposition or atomic layer deposition operation to form thin films on the surface of each substrate. After forming thin films, the processed substrates are retrieved by following the reversed steps.

Embodiment 3

In Embodiment 2, the arm axis 292 moves in three ways; up and down motion and a rotational motion referring to FIGS. 2A and 2B. Instead, a substrate (not shown) can be loaded and unloaded by changing the arm axis 292 movement to rotational motion only, and also by changing the movement of the substrate supporting pin 272 to up and down motion actively by installing a center drive motor 286 as illustrated in FIG. 2C according to the present invention. A similar illustration on the substrate supporting pin 160 with a center drive motor 164 is as shown in FIG. 1B.

A deposition apparatus according to the exemplary Embodiment 3 is illustrated in FIG. 2A. The substrate supporting pin 272 in FIG. 2B moves up and down passively, but in FIG. 2C. the substrate supporting pin 272, and associated center shaft 274 moves up and down actively by the center drive motor 288 such as a air pressure cylinder attached to the bottom of the center shaft 274 and the substrate supporting pin 272. FIG. 2C is a cross-sectional schematic drawing illustrating a deposition apparatus according to the exemplary Embodiment 3 according to the present invention, and FIG. 2c is a cross-sectional view of the schematic drawing FIG. 2a along a dotted line A-A′. FIG. 2C illustrates a center drive motor 288 attached to the substrate supporting pin 272 through a center shaft 274 so that the substrate supporting pin 272 moves up and down actively for loading and unloading a substrate (not shown).

In Embodiment 3 according to the present invention, a substrate (not shown) is loaded onto one of the three reactor lower bodies 220a, 220b, 220c following the steps described below. Initially, the three reactor lower bodies 220a, 220b, 220c are empty. Those three reactor lower bodies 220a, 220b, 220c are lowered and also those three substrate supporting pins 272 (three of them) are lowered down below the height of the arms 290a, 290b, 290c. Initially the arms 290a, 290b, 290c are in “park” position as shown in FIG. 2A. The arm set 290a, 290b, 290c is rotated either clockwise or counter clockwise by 60° so that the first arm 290a is lined up with the first reactor lower body 220a. A substrate is transported onto the first arm 290a through the substrate loading and unloading gate 240, where the first substrate (not shown) is placed on top of the first arm 290a above the reactor lower body 220a.

The arm axis 292 is rotated counter clockwise (or clock wise) by 120° so that the empty second arm 290b is positioned horizontally in line with the substrate loading and unloading gate 240 in FIG. 2A, and also the empty second arm 290b is positioned vertically in line with the first reactor lower body 220a. A second substrate 225 (not shown) is placed on the second arm 290b through the substrate loading and unloading gate, and then likewise the arm axis 292 is rotated another 120° counter clockwise (or clockwise) so that the empty third arm 290c is horizontally lined up with the substrate loading and unloading gate 240, or the empty third arm 290c is vertically lined up with the first reactor lower body 220a, Next, a third substrate (not shown) is transported through the substrate loading and unloading gate 240 and placed on the third arm 290c.

Next, three substrate support pins 272 (three of them) are raised higher than the three arms 290a, 290b, 290c, so that those three substrate support pins support the three substrates, one on each pin. Here, those three pins 272 do not interfere with the three arms 290a, 290b, 290c. Thereafter, the arm axis 292 is rotated by 30° so that the three hook-like pins clear from those three reactors or the reactor lower bodies 220a, 220b, 220c. Then, three reactor lower bodies 220a, 220b, 220c are raised up to make a vacuum-tight contacts ready for a Chemical Vapor Deposition or an Atomic Layer Deposition operations to form thin films. After forming thin films, the processed substrates (not shown) are retrieved by following the steps described above in reversed order.

Embodiment 4

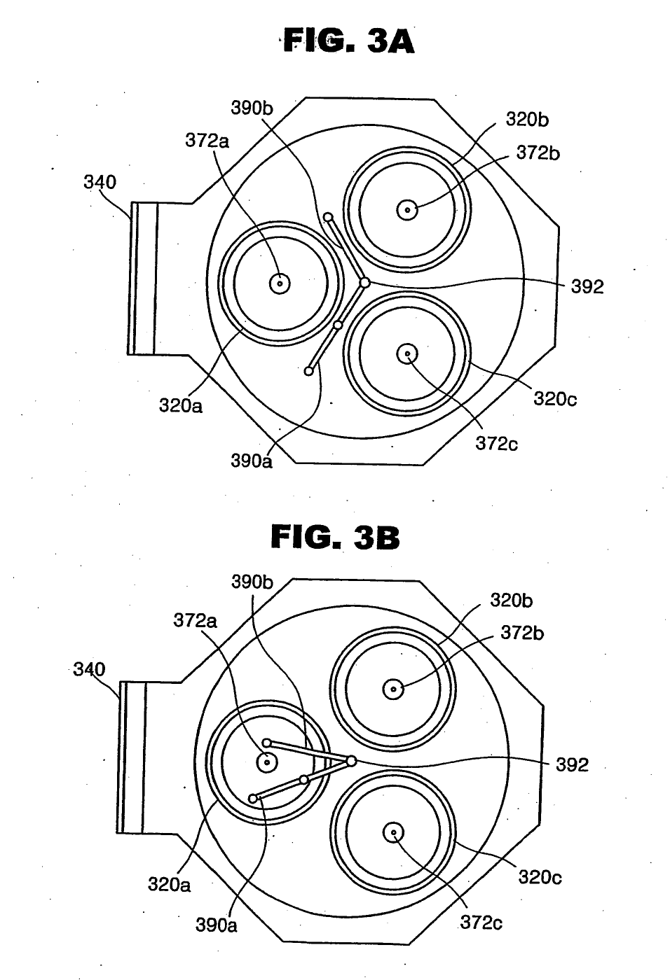

In order to reduce the size of the deposition apparatus, it is desirable to place several reactors closer together each other. In Embodiment 2 as described above, where three hook-like substrate transport arms 290a, 290b, 290c, the reactors (or reactor lower bodies) can not be placed closer than the spread of those three “hooks” for the substrates. This problem becomes severe when larger substrates such as 300 mm substrates are to be processed. Therefore, in this case, instead of using three symmetrically and triangularly arranged arms 290a, 290b, 290c, a pain of rod-like arms 390a and 390b as shown in FIGS. 3A and 3B may be used for transporting the substrates. FIGS. 3A and 3B illustrates a pain of rod-like arms used in contacting a deposition apparatus. Two arms 390a, 390b can make rotational movements independently each other with a common center of rotation 292, or two arms 390a, 390b can make rotational movement together, yet maintaining a fixed angle between those two angles.

Referring to FIGS. 3A and 3B, where the chamber cover (not shown) and the reactor upper bodies 320a, 320b, 320c are identical to those in Embodiment 1 and the detailed descriptions associated with the chamber cover and the reactor upper bodies 320a, 320b, 320c are omitted here. Two rod-like arms 390a, 390b are attached to an arm axis 392 to form a rotating arm set. The “park” position of the arms is as shown in FIG. 3A, and this position is a resting position of the arms while the reactors in a closed position are processing the deposition steps. A arm center drive motor 286 in FIG. 2C as an example is attached to the bottom of the arm axis 392 in FIG. 3A so that the arm axis rotates. Also, at the bottom of the substrate support pin 372a, 372b, 372c, a center drive motor such as an air pressure cylinder, so that the substrate supporting pin 372a, 372b, 372c can be moved up and down. In order to transport a substrate after the completion of a thin film formation, the reactor lower bodies 320a, 320b, 320c and the substrate supporting pins 372a, 372b, 372c are lowered and then the first substrate supporting pin 372a is raised above the height of the arms 390a, 390b, thereby the first substrate (not shown) is separated from the first reactor lower body 320a and is supported by the first substrate supporting pin 372a. At this time the arms 390a and 390b are positioned as shown in FIG. 3a, and the record and the third substrates are still remained in the reactor lower bodies 320b and 320c.

Next, as shown in FIG. 3B, the arm axis 392 is rotated in such a way that the two arms 390a, 390b can hold and support the substrate above them. Next, the substrate supporting pin 372a is lowed so that the substrate (not shown) is landed on the arms 390a, 390b and supported by them. The first arm 390a has two bumps protruded upwards, one at the end of the arm and the other in the middle of the arm and the second arm 390b has one “bump” protruded upwards at the end of the arm as marked with three small circles in FIG. 3B, where the substrate is supported by these three upward bumps on the arms 390a and 390b. Since the substrate supporting pin 372a is located between the opening of the two arms 390a and 390b, the substrate is supported by those three bumps on the arms stably and securely. The substrate is then transported to the outside of the reactor and the chamber through the substrate loading and unloading gate 340.

In order to retrieve the second processed substrate, the two arms 390a, 390b are moved to the original “parked” position, and then rotated 120° counterclockwise (or clockwise) so that the arms 390a, 390b and the second reactor lower body 320b are lined up. The second substrate is separated from the second reactor lower body 320b by raising the second substrate supporting pin 372b at the level above the arms 390a, 390b, and then said substrate is supported with the substrate supporting pin 372b alone. The angle between the arms 390a, 390b is reduced to fold the arms and then the arms 390a, 390b are rotated so that these arms can support and hold the second processed substrate, Next, the second substrate supporting pin 372b is lowered to support the substrate with two arms 390a, 390b alone, while maintaining the angle between two arms 390a, 390b, the arms are rotated by 240° so that the arms loaded with the second processed substrate are lined up with the substrate loading and unloading gate 340, and through this gate 340, the second processed substrate is transported to the outside of the chamber, and is retrieved.

Finally, in order to retrieve the third processed substrate, the position of the arms 390a, 390b is restored back to the position shown in FIG. 3A, and then the arms are rotated by 240° so that two arms 390a, 390b are positioned above the third reactor lower body 320c. The third substrate supporting pin 372c is raised at the level above the height of the arms 390a, 390b, to separated the third processed substrate (not shown) from the third reactor lower body 320c and then to support the third processed substrate with the third substrate supporting pin 372c. The angle between the arms 390a, 390b is reduced to fold the arms 390a, 390b and the arms are rotated in such a way that the position of the arms is lined up with the third reactor lower body 320c. Then, two arms 390a, 390b support the third processed substrate (not shown) by lowering the third substrate supporting pin 372c. While maintaining the angle between the arms 390a, 390b, the arm assemble is rotated by 120° the arm assemble loaded with the third processed substrate is lined up with the substrate loading and unloading gate 340, and through this gate 340, the third processed substrate is transported to the outside of the chamber, and is retrieved.

Following the steps described above, all three processed substrates are retrieved after thin films are formed on the substrates. For loading substrates onto the reactor lower bodies, the same steps are followed in the reversed order.

The rotational monument of the arms for loading and unloading the substrates is a relative movement with respect to the rotational movement of the base plate 130 in FIG. 1B, for example. In other words, the same loading and unloading of the substrates can be achieved by rotating the base plate in Embodiment 1 with all three reactor lower bodies in detached position from the reactor upper bodies or similar mechanisms in other Embodiments instead of rotating the arm assembly according to another aspects of the present invention.

In a deposition apparatus, the process time of a substrate is a sum of the substrate transfer time including loading and unloading t_{transfer}, the stabilization time for temperature and pressure between the processing steps, t_{wait}, and the actual processing time t_{process}. For a single substrate deposition apparatus, the total time required to process three separate substrates is three times of the time required for processing one substrate, that is t_{3substrate}=3×(t_{1substrate}+t_{wait}+t_{process}). For example, when the time for loading and unloading, t_{transfer}, is 20 seconds, the stabilization time, t_{wait}, is 60 seconds, and the actual processing time, t_{process}, is 180 seconds, it takes 780 seconds or 13 minutes for processing three substrates by using a single substrate processing type of deposition apparatus, while it takes only 300 seconds or 5 minutes. Therefore, the single substrate processing type of deposition apparatus takes 2.6 times longer than three substrate processing type. In general, the deposition apparatus capable of n number of substrates can process

$$\begin{matrix}K = n \times ( {t}_{transfer} + {t}_{wait} + {t}_{process} ) / ( n \times {t}_{transfer} + {t}_{wait} + {t}_{process} ) \\ = n - n ( n - 1 ) \times {t}_{ransfer} / ( n \times {t}_{transfer} + {t}_{wait} + {t}_{process} )\end{matrix}$$

more than a single substrate processing type of deposition apparatus.

In general, it is very difficult to use a process method developed for one system for another system, because the gas distribution system developed for a single substrate processing apparatus differs significantly from a multiple substrate processing apparatus. However, according to the present invention, a processing method developed for a single substrate processing type of deposition apparatus can be used for a multiple substrate processing type of deposition apparatus without changing or modifying the process method developed for a single substrate processing type, because multiple reactors perform the same way as a single reactor when the gas inlets are fed with gases independently with respect to each other and the gas outlets are exhaust the processed gases independently with respect to each other, and also uniformly feed gases and uniformly evacuate or purge the reactors according to the present invention due to the fact that the reactors are identical. Furthermore, by supplying the process gases to several reactors using identical gas supply systems as to a single substrate reactor, such uniformity of the process gases described above can be maintained. In general, a source gas supply system having a capacity of supplying n times of the source gas required for one reactor can be rearranged so that the same gas supply system supplies uniformly to n reactors in gas flow rate and quantity same as supplying a single processing reactor. In case of using one gas supply systems, the gas supply system cost can be reduced simply because only one gas supply system is used instead of using n identical gas supply systems.

Similarly, using only one gas discharge system, the associated cost can be reduced simply because one gas exhaust system with one vacuum pump, can remove gases from n reactors at the same flow rate and quantity since n identical reactors are used according to the present invention.

In addition, it is advantageous to use same functioning apparatus, yet takes up less space for the apparatus. Accordingly, it is also advantageous to use multiple identical reactor chamber, wherein multiple of substrates can be processed in a given process module according to the present invention in a environment where three separate process module are attached to a substrate transfer module, among which one of the process modules is the thin film deposition module capable of handling multiple number of modules according to the present invention, compared to the case of a single substrate type of thin film deposition tool and an associated substrate transport module.

Furthermore, there are additional advantages of structuring an integrated system by combining and integrating several independent reactors according to the present invention. In a conventional process chamber, only one unique reactor for each process and one set of dedicated robot arm are used for each chamber. But according to the present invention, one robot arm can be shared by several reactors. Furthermore, as in a chemical vapor deposition or an atomic layer deposition processes, where the process gas supply is carried out in sequential timing cycles, the throughput of the substrate processing can be increased by adjusting the timings between the reactors. Of course, there is an advantage of reducing the area required for setting up the apparatus according to the present invention.

The best modes for carrying out the present invention are described above in detail, but the descriptions presented in the Embodiments are not intended to limit the scope of the basic principles and ideas of the present invention. Those who are familiar with the art should be able to readily derive or extend the ideas, principles and variations of the present invention.

As afore-described, according to the present invention, a plural of independent and identical reactors are used for structuring a deposition apparatus, and such integrated apparatus is capable of processing thin film deposition steps much more efficiently compared to the case of using a single substrate type of deposition reactor. Also, the space or footprint the integrated deposition apparatus takes up is much move reduced compared with multiples of single substrate reactors, thereby, use of the integrated deposition apparatus is much more economically efficient in terms of number of substrates to be processed per unit time. Furthermore, the process conditions developed using a single substrate type of deposition reactor can be used for processing substrates using said integrated deposition apparatus without a major adjustments, thereby the deposition apparatus according to the present invention can be easily applied to mass production applications.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An apparatus for depositing thin films as a chamber surrounded by a base plate a chamber wall and a chamber cover comprising;
a reactor upper body attached to said chamber cover,
a reactor lower body installed to said base plate that moves up and down and defines a reactor together with said reactor upper body,
a reactor defined by a said reactor upper body and said reactor lower body including a substrate supporting pin mounted at the center of the base of said reactor lower body,
said chamber wall having a substrate loading and unloading gate located on the side of said chamber wall, and said chamber having at least two said reactors.

2. The apparatus of claim 1, wherein said respective reactor lower body moves up and down together, driven by main drives.

3. The apparatus of claim 1, wherein said reactor upper body is equipped with a process gas inlet hole and a process gas outlet through said chamber cover so that said inlet and outlet hales one connected to a process gas supply system and a process gas exhaust system, respectively.

4. The apparatus of claim 1, wherein a process gas supply system is installed to said chamber cover, where the process gas supply tubes are arranged in a mutually symmetrical fashion with respect to the relative locations of said reactor upper bodies.

5. The apparatus of claim 1, wherein said process gas discharge system is installed to said chamber cover, where the process gas exhaust tubes are arranged in a symmetrical fashion with respect to the relative locations of said reactor upper bodies.

6. The apparatus of claim 1, wherein said reactor lower bodies are attached to said base plate and said base plate is rotated by a master drive.

7. The apparatus of claim 1, wherein said apparatus further comprises:
a set of hook-shaped arm set that rotates around an arm axis and also moves up and down so that a substrate is loaded and unloaded into and out of said reactor.

8. The apparatus of claim 7, wherein a set of drives that rotates said set of arms around a rotational axis located at the center of the base plate and moves up and down, is attached to the arm shaft.

9. The apparatus of claim 1, wherein said apparatus further comprises a set of hook-like arm set that rotates around an arm axis and also moves up and down so that a substrate is loaded and unloaded into and out of said reactors.

10. The apparatus of claim 9, wherein a drive is attached at the bottom of the center shaft of said arm set so that said drive rotates the arm set around the center axis located at the center of said base plate.

11. The apparatus of claim 1, wherein said substrate supporting pin moves up and down by a drive unit at the bottom of said substrate supporting pin.

12. The apparatus of claim 7, wherein the open space of the hook-shaped arm is larger than the diameter of said substrate supporting pin.

13. The apparatus of claim 7, wherein the number of the arms is the same as the number of said reactors, and while the formation of thin films on said substrate, said arms are placed between two reactors.

14. The apparatus of claim 1, the apparatus further comprises, a rod-like two arms are attached to said reactor instead of hook-like arms.

15. The apparatus of claim 14, wherein a drive is attached to the bottom of said arm shaft so that said arm set an be rotated around the rotational axis located at the center of said base plate.

16. The apparatus of claim 14, wherein a drive unit is attached to said substrate supporting pin so that said substrate supporting pin can move up and down, and each substrate supporting pin moves up and down independently with each other.

17. The method of using the apparatus of claim 6, comprising:
moving downward said reactor lower body that is in contact with said reactor upper body,
for each one of the reactors, sequentially one at a time repeatedly loading a substrate transported through a substrate loading and unloading gate on a substrate supporting pin after lining up said substrate supporting pin with said substrate loading and unloading gate by rotating a base plate,
moving said reactor lower body upward so that said reactor lower body makes a vacuum-tight contact with said reactor upper body.

18. The method of using the apparatus of claim 7, comprising:
moving downward said reactor lower body that is in contact with said reactor upper body, and moving the arms upward to the height higher than said substrate supporting pin,
for each one of said arms, sequentially, one at a time and repeatedly loading a substrate transported through the substrate loading and unloading gate on an arm after lining up said arm with said substrate loading and unloading gate by rotating said arms,
lowering said arms to the height lower than the height of said substrate supporting pin so that said substrate support pin supports and holds said substrate after rotating said arm set so that the open space of the hook-shaped arms is lined up with said substrate supporting pins,
rotating said arms to a position so that said arms do not interfere with reactor lower bodies,
moving said reactor lower bodies upward so that said reactor lower bodies make a vacuum-tight contact with said reactor upper bodies, individually, in pairs.

19. The method of using the apparatus of claim 9, comprising:
moving downward said reactor lower bodies that is in contact with said reactor upper bodies, and also moving said substrate supporting pins to the height lower than the height of said arms,
for each one of said arms, sequentially, one at a time and repeatedly, loading a substrate transported through said substrate loading and unloading gate on an arm after lining up said arm with said substrate loading and unloading gate by rotating the arms,
supporting said substrates, one at a time, on a substrate supporting pin by raising said substrate supporting pins through the middle of the open space of said hook-shaped arms, after lining up said hook-shaped arms with said substrate supporting pins in such a way that the substrate supporting pins are positioned in the middle of said hook-shaped arms,
rotating said arms to a position so that said arms do not interfere with said reactor lower bodies,
moving said reactor lower bodies upwards so that said reactor lower bodies make a vacuum-tight contact with said reactor upper bodies, individually, in pairs.

20. The method of using the apparatus of claim 14, comprising:
moving downward said reactor lower bodies that is in contact with said reactor upper bodies, and also moving said substrate supporting pins to the height lower than the light of said arms,
for each one of the reactors, sequentially one at a time and repeatedly, moving said substrate supporting pins that support said substrates downward, after said two arms are lined up with said substrate loading and unloading gate by rotating said two arms, placing safely on said arms the substrates transported through said substrate loading and unloading gate, moving said arms to the position where said substrates are to be placed by rotating said arms, while maintaining the same angle between two arms, supporting said substrates with said substrate supporting pins by raising said substrate supporting pins through the open space between two arms, and rotating said two arms to a position so that said tow arms do not interfere with the downward movement of said substrate supporting pins that support said substrate while maintaining an open angle between two said arms,
placing said tow arms to a position so that said two arms do not interfere with said reactor lower bodies by rotating said two arms, and
moving said reactor lower bodies upward so that said reactor lower bodies make a vacuum-tight contact for processing said substrates inside said reactor.
